(19) United States
(12) Patent Application Publication
(10) Pub. No.: US 2007/0085220 A1
(43) Pub. Date: Apr. 19, 2007

(54) Re-enforced ball-grid array packages for semiconductor products

(76) Inventor: Edgardo R. Hortaleza, Garland, TX (US)

Correspondence Address: TEXAS INSTRUMENTS INCORPORATED, P O BOX 655474, M/S 3999, DALLAS, TX, 75265, US

(21) Appl. No.: 11/253,485

(22) Filed: Oct. 19, 2005

(51) Int. Cl. H01L 23/48

(52) U.S. Cl. 257/780

(57) ABSTRACT

A semiconductor device (700) comprising a sheet-like substrate (701) of insulating material, the substrate having first and second surfaces; a plurality of conductive terminals (702) on the first substrate surface; at least one elastic member (705) protruding from each terminal; the members at least partially enclosed by a reflow element (704) attached to the respective terminal. The members are shaped to withstand mechanical stress exerted on the element; they may be one ore more straight pins, or a pin with one or more bendings. A semiconductor chip (710) is assembled on the second substrate surface.

### FIELD OF THE INVENTION

The present invention is related in general to the filed of semiconductor devices and processes and more specifically to structure and assembly method of high density solder ball grid array packages featuring high reliability.

### DESCRIPTION OF THE RELATED ART

During and after assembly of an integrated circuit (IC) chip to an external part such as a circuit board by solder reflow, and then during device operation, significant temperature differences and temperature cycles appear between the semiconductor chip and the board. This is especially true of flip-chip type mounting schemes. The reliability of the solder joint is strongly influenced by the coefficients of thermal expansion of the semiconductor material and the board material. For example, there is more than one order of magnitude difference between the coefficients of thermal expansion of silicon and FR-4. This difference causes thermo-mechanical stresses, most of which are absorbed by the solder joints.

Thermo-mechanical stress difficulties are aggravated by coplanarity problems of the solder balls and the difficulties involved in obtaining a favorable height-to-diameter ratio and uniformity of the solder interconnection. These difficulties start with the solder ball attach process. As an example, when solder paste is dispensed, the volume of solder paste may vary in volume, making it difficult to control the solder ball height. When prefabricated solder balls are used, the difficulty of avoiding a missed attachment site is well known.

Furthermore, evidence suggests that solder connections of short length and non-uniform width are unfavorable for stress distribution and strain absorption. The stress remains concentrated in the region of the chip-side solder joint, where it may lead to early material fatigue and crack phenomena. Accordingly, solder connections of generally spherical shape are likely to be more sensitive to stress than elongated connections.

The fabrication methods and reliability problems involving flip-chips re-appear, in somewhat modified form, for ball-grid array type packages, including chip-scale packages (CSP). Most CSP approaches are based on flip-chip assembly with solder bumps or solder balls on the exterior of the package, to interface with system or wiring boards.

Following the solder reflow step, flip-assembled chips and packages often use a polymeric underfill between the chip, or package, and the interposer, substrate, or printed circuit board (PCB). These underfill materials alleviate some of the thermo-mechanical stress caused by the mismatch of the coefficients of thermal expansion (CTE) of package components. But as a process step, underfilling is time-consuming and expensive, and is preferably avoided.

During the last decade, a number of variations in device structure, materials, or process steps have been implemented in manufacturing in order to alleviate the thermo-mechanical stress problem. All of them suffer from some drawback in cost, fabrication flow, material selection, and so forth.

### SUMMARY OF THE INVENTION

Applicant realizes the need for a coherent, low-cost methodology of assembling flip-chip integrated circuit chips and semiconductor devices that provides a high degree of thermo-mechanical stress reliability. The methodology should be flexible enough to be applied for different semiconductor product families and a wide spectrum of design and process variations. Preferably, these innovations should be accomplished using the installed equipment base so that no investment in new manufacturing machines is needed.

One embodiment of the invention comprises a substrate, which has a sheet-like base of insulating material with first and second surfaces. A conductive terminal is on the first base surface. A reflow element is attached to the terminal. At least one elastic member is inside the element. This member is protruding from the terminal and shaped to withstand mechanical stress exerted on the element. The member may be formed as one or more straight pins, or as a pin with one or more bendings to enable spring-like reaction, or as a spring; the member may have a surface composition metallurgically suitable for solder attachment, such as nickel or palladium.

The second base surface may be suitable for the assembly of a semiconductor chip.

Another embodiment of the invention is a semiconductor device consisting of a substrate as described above and a semiconductor chip assembled on the second base surface. Further, the device may include encapsulation material surrounding the chip.

Another embodiment of the invention is an electronic system comprising a semiconductor device and a circuit board. The device consists of a sheet-like substrate of insulating material with first and second surfaces, a plurality of conductive terminals on the first base surface, at least one elastic member protruding from each terminal, the members enclosed by a reflow element attached to the respective terminal and shaped to withstand mechanical stress exerted on the element, and a semiconductor chip assembled on the second base surface. The circuit board has a plurality of conductive terminals in locations matching the locations of the terminals on the first base surface. Reflow elements are attached to the terminals on the first base surface and also to the terminals of the circuit board, one by one.

Another embodiment of the invention is a method for fabricating a substrate for the assembly of semiconductor devices. The method provides a sheet-like base of insulating material with first and second surfaces; the second surface may be suitable for the assembly of a semiconductor chip. A conductive terminal is then formed on the first base surface. At least one elastic member is attached to the terminal so that the at least one member protrudes from the terminal; the at least one member is shaped to withstand mechanical stress. A reflow element is finally attached to the terminal so that the element encloses the at least one member.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section of a portion of a substrate having a contact pad and an attached reflow element, in known technology.

FIG. 2 shows a schematic cross section of a portion of a substrate having a contact pad with an attached reflow element according to an embodiment of the invention, wherein the pad has an attached elastic member shaped to withstand mechanical stress exerted on the reflow element.

FIG. 3 shows a schematic cross section of a portion of a substrate having a contact pad with an attached reflow element according to another embodiment of the invention, wherein the pad has an attached elastic member shaped to withstand mechanical stress exerted on the reflow element.

FIG. 4 shows a schematic cross section of a portion of a substrate having a contact pad with an attached reflow element according to another embodiment of the invention, wherein the pad has an attached elastic member shaped to withstand mechanical stress exerted on the reflow element.

FIG. 5 shows a schematic cross section of a portion of a substrate having a contact pad with an attached reflow element according to another embodiment of the invention, wherein the pad has an attached elastic member shaped to withstand mechanical stress exerted on the reflow element.

FIG. 6 shows a schematic cross section of a portion of a substrate having a contact pad with an attached reflow element according to another embodiment of the invention, wherein the pad has an attached elastic member shaped to withstand mechanical stress exerted on the reflow element.

FIG. 7 is a schematic cross section of a semiconductor device having a substrate with a plurality of contact pads and attached reflow elements according to an embodiment of the invention, wherein the pads have attached elastic members shaped to withstand mechanical stress exerted on the reflow elements.

FIG. 8 is a schematic cross section of an electronic system comprising a semiconductor device attached to a circuit board by reflow elements, which have, according to an embodiment of the invention, elastic members attached to the device pads and shaped to withstand mechanical stress exerted on the reflow elements.

### DETAILED DESCRIPTION OF THE PREFERRED EMBODIMENTS

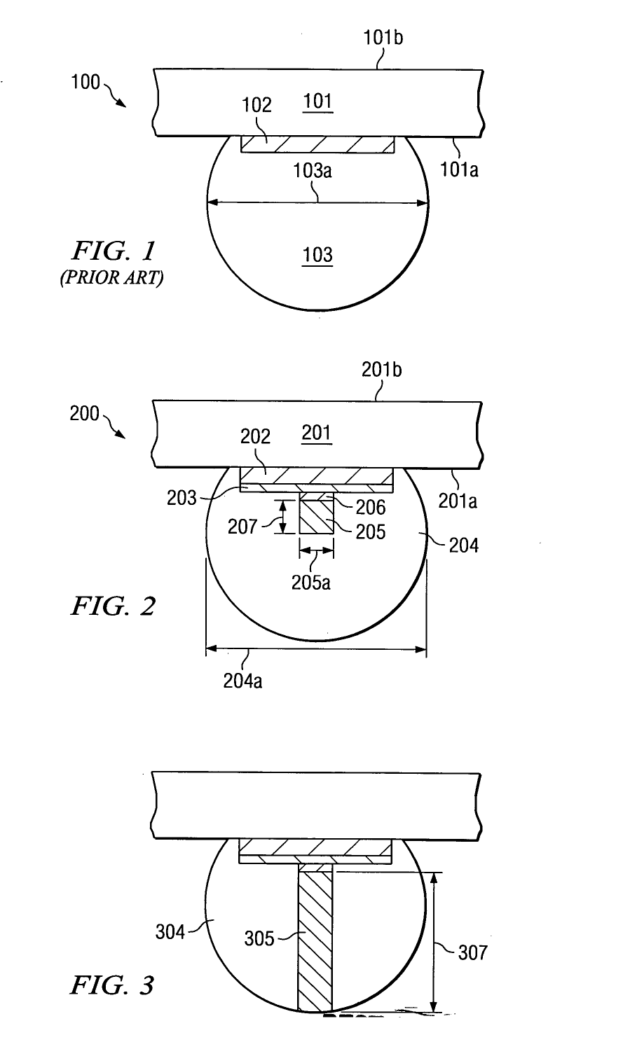

As a typical example of the known technology, the schematic cross section of FIG. 1 illustrates a solder ball (solder bump) connection generally designated 100. In this connection, an insulating substrate 101 with first surface 101a and second surface 101b has a metal layer on first surface 101a. A typical example of the metal is copper. The patterned portion 102 of this metal layer represents a conductive terminal and is contacted by a reflow element 103, usually a solder body (“ball”, bump) containing tin or a tin alloy. In order to facilitate the attachment of the reflow element, the terminal 102 commonly has a solderable surface; examples include nickel, palladium and gold.

The dimensions of terminal 102 are related to the need of creating a large enough interface between reflow element 103 and metal 102 to insure a reliable solder joint after reflow, especially when connection 100 is employed for attaching the substrate to a circuit board. Thermo-mechanical stresses are exerted in the attaching process as well as typically during the operation of the assembly. As a consequence of this reliability requirement, terminal 102 has to consume significant amounts of area. As a common example, terminal 102 has to be sized from about 50% to about 75% of the diameter 103a of the reflow element.

Experience has shown, however, that even with large-sized terminals, the reliability of the solder joints is often risky, especially in the recently required drop tests. FIGS. 2 to 6 illustrate embodiments of the present invention, which greatly enhance the reliability of solder reflow interconnections, even under the most demanding stress test conditions.

FIG. 2 illustrates a portion of a substrate generally designated 200, which has a sheet-like base 201 made of insulating material or of a laminated stack of alternating insulating and conducting layers. Base 201 has a first surface 201a and a second surface 201b. A conductive terminal 202 is on the first base surface 201a. Terminal 202 is preferably formed from a layer of copper or copper alloy in the thickness range from about 5 to 35 μm; thicker terminals may be used. Alternatively, aluminum may be used. In order to facilitate solderability, terminal 202 may have a thin surface layer 203 of gold or of a stack of nickel followed by gold.

A reflow element 204 is attached to terminal 202. Preferred materials for element 204 are tin or a tin alloy, binary or ternary; other options include indium or an indium alloy. The diameter 204a of reflow element 204 is determined by the lateral dimensions of terminal 202.

Inside reflow element 204 is at least one elastic member 205, which protrudes from the terminal 202. Preferably, member 205 is electrically conductive; in other embodiments, it may be an insulator. In FIG. 2, member 205 is formed as a straight pin made preferably of an iron-nickel-cobalt alloy, which is attached to terminal 202 by a brazed layer 206 of a silver-copper alloy. Alternatively, member 205 is made of copper and directly attached to terminal 202. It is advantageous to use members with a surface composition metallurgically suitable for solder attachment; examples are thin layers (flashes) of nickel, gold or palladium, or alloys thereof. The diameter 205a of member 205 is preferably between about 7 and 15% of the diameter 204a of reflow element 204. Embodiments with larger diameter members have been fabricated.

In the embodiment of FIG. 2, the length 207 of member 205 reaches approximately to the center of reflow element 204 and is thus relatively short. In the embodiment of FIG. 3, the length 307 of pin 305 reaches approximately to the perimeter of reflow element 304 and is thus considerably longer. Substrates with these pin lengths are applicable to ball grid array packages for semiconductor devices. In embodiments wherein the pin length is larger than the diameter of the reflow element, the substrate is applicable to pin grid array packages for semiconductor devices.

The second surface 201b of the substrate base 201 is in many applications suitable for the assembly of a semiconductor chip. When semiconductor devices are fabricated by such assembly, the devices are typically attached in a subsequent assembly step to external boards using the reflow elements 204 for the attachment process. Since typically materials of widely different coefficients of thermal expansion are used in semiconductor devices and boards, thermo-mechanical stresses are exerted on the solder joints in the assembly steps as well as later by temperature excursions in device tests and operations. The solder joints in devices with solder connections strengthened by the pins of the invention illustrated in FIGS. 2 and 3, show greatly increased reliability in the device assembly process steps and stress testing. The reliability can be further enhanced in embodiments with modified pin structures as described below.

Referring now to FIG. 5, an embodiment is illustrated with more than one straight elastic member attached to the substrate terminal 502. The members shaped as pins may even have different diameters: Pin 505 is thicker than pin 506 and 507. Furthermore, the pins may be attached to terminal 502 at different angles, offering a control of the solder ball diameters after reflow.

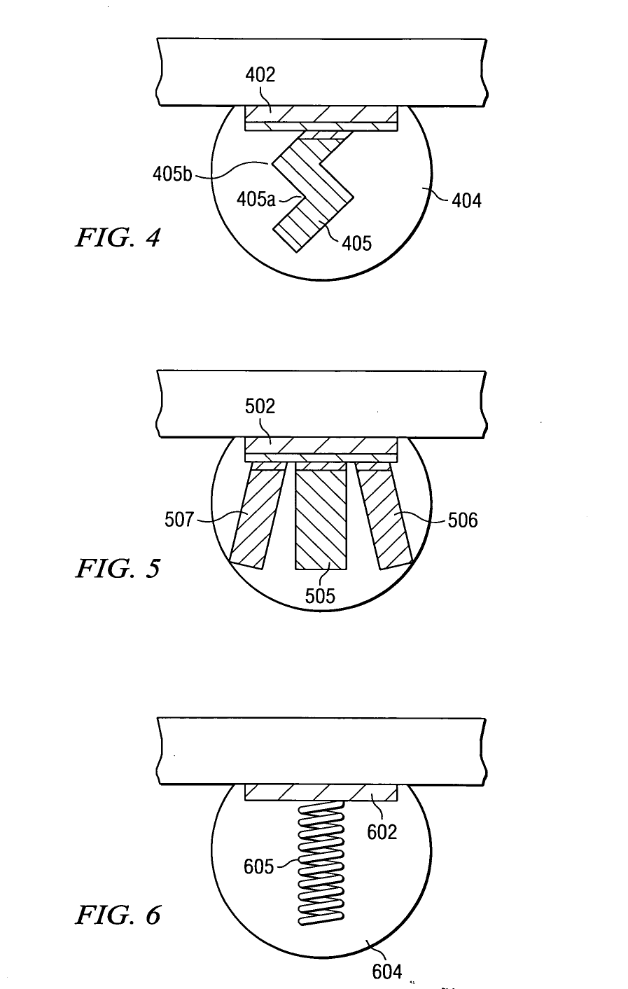

Referring to the embodiment of FIG. 4, the elastic member 405 attached to the conductive terminal 402 and embedded in the reflow element 404, has been formed to have one or more bendings 405a, 405b, . . . , in order to enable a spring-like reaction of the elastic member. This shape of the member has been proven to be particularly effective in providing solder joint reliability, while retaining simplicity in the fabrication process.

The concept of a spring-shaped elastic member is carried one step further by the embodiment of FIG. 6. A spring 605 of one or more windings, made of a suitable material such as iron-nickel-cobalt alloy, copper alloy, or copper and preferably having a surface composition metallurgically suitable for solder attachment, is brazed on terminal pad 602. Preferably, the spring is for the most part or completely embedded in the reflow element 604. The thickness of the spring wire depends on the number of windings; the best results for solder joint reliability have been obtained by a spring made of one or two windings of a wire with a diameter between about 7 and 15% of the diameter of the reflow element and a surface with a thin layer (flash) of palladium or gold.

Another embodiment of the invention is schematically illustrated in FIG. 7. A semiconductor device, generally designated 700, has a substrate 701 of insulating base material and first surface 701a and second surface 701b. A plurality of conductive terminals 702 are positioned on first surface 701a. From each terminal, at least one elastic member 705 is protruding. The member 705 is preferably elongated and made of conductive material brazed onto the metallic terminal. The member 705 is at least partially enclosed by a reflow element 704, which is attached to the respective terminal. Member 705 is shaped to withstand mechanical stress exerted on the reflow element. A semiconductor chip 710 is assembled on the second substrate surface 701b. In FIG. 7, bonding wires 711 are chosen to provide the electrical connections from the chip input/output pads to the contact pads on the second substrate surface; other devices may use flip-chip assembly to accomplish the connection. Encapsulation material 720 surrounds the assembled chip 710.

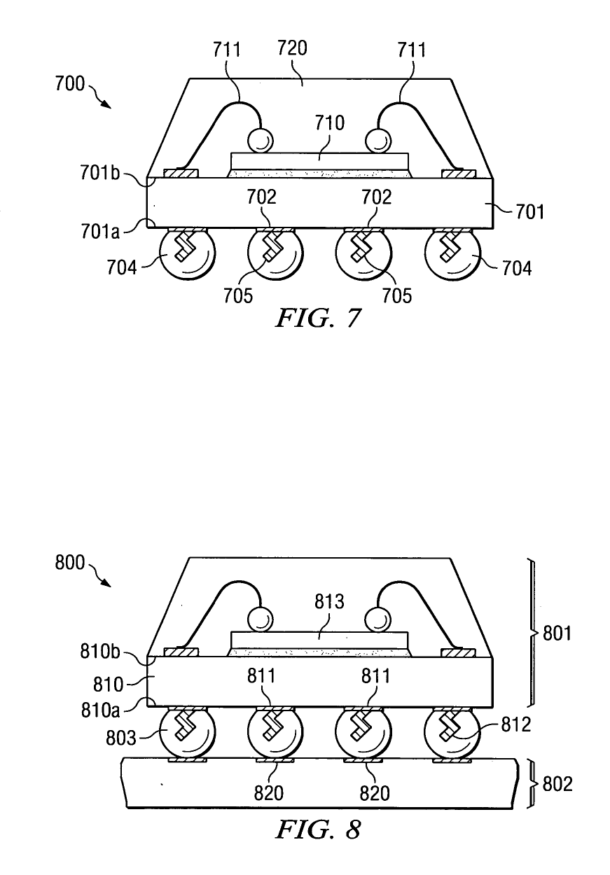

Another embodiment of the invention is schematically illustrated FIG. 8. An electronic system, generally designated 800, has a semiconductor device 801, a circuit board 802, and reflow elements 803.

The semiconductor device has an insulating substrate 810 with first surface 810a and second surface 810b. A plurality of conductive terminals 811 are on first substrate surface 810a. At least one elastic member 812 is protruding from each terminal 811. The members are enclosed, at least partially, by a reflow element 803, which is attached to the respective terminal 811. The members 812 are shaped to withstand mechanical stresses exerted on the reflow element; in the example of FIG. 8, the members 812 have a couple of bendings to provide a spring-like reaction to stress. A semiconductor chip 813 is assembled on the second substrate surface 810b.

The circuit board 802 has a plurality of conductive terminals 820 in locations, which match the locations on the terminals 811 on the first substrate surface 810a.

The reflow elements 803, which are attached to the terminals 811 on the first substrate surface 810a, are also attached to the terminals 820 of the circuit board 802, one by one. It is this arrangement, which causes frequently significant amounts of thermo-mechanical stress on the solder joints, because of the differences in the coefficient of thermal expansion between the materials of the device 801 (especially the semiconductor chip) and the circuit board 802 (frequently a plastic-based material such as FR-4). The embodiment of FIG. 8 makes the stress withstanding and stress-absorbing benefit of the elastic members inside the reflow elements according to the invention evident.

Another embodiment of the invention is a method for fabricating a substrate. A sheet-line substrate of insulating material is provided, which has first and second surfaces. Conductive terminals are formed on the first substrate surface. At least one elastic member is attached to each terminal so that this at least one member protrudes from the terminal. A preferred method is a brazing technique. The member is shaped to withstand mechanical stress. Finally, a reflow element such as a solder ball is attached to each terminal so that the element encloses the at least one member. The second surface of the substrate may be suitable for the assembly of a semiconductor chip.

Another embodiment of the invention is a method for assembling a semiconductor device. A sheet-line substrate of insulating material is provided, which has first and second surfaces. A plurality of conductive terminals is formed on the first substrate surface. At least one elastic member is attached to each terminal so that this at least one member protrudes from the terminal. A preferred method is a brazing technique. The member is shaped to withstand mechanical stress. Next, a semiconductor chip is provided. The chip is assembled on the second substrate surface. Finally, a reflow element such as a solder ball is attached to each terminal so that the element encloses the at least one member.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the base material of the substrate may be compliant instead of stiff; preferably, the temperatures used in the member brazing process remain within the elastic regime of the material.

As another example, the members may be heated to facilitate an easy solder reflow step associated with attaching the solder ball to the package.

As another example, the encapsulation compound may be added after the solder elements are attached.

It is therefore intended that the appended claims encompass any such modifications or embodiments.

I claim:

1. A substrate comprising:
a sheet-like base of insulating material, the base having first and second surfaces;
a conductive terminal on the first base surface;
a reflow element attached to the terminal; and
at least one elastic member inside the element, the member protruding from the terminal and shaped to withstand mechanical stress exerted on the reflow element.

2. The substrate according to claim 1 wherein the second base surface is suitable for the assembly of a semiconductor chip.

3. The substrate according to claim 1 wherein the member is electrically conductive.

4. The substrate according to claim 3 wherein the member is one or more straight metal pins.

5. The substrate according to claim 3 wherein the member is a metal pin having one or more bendings to enable spring-like reaction.

6. The substrate according to claim 3 wherein the member is a metal spring.

7. The substrate according to claim 1 wherein the member has a surface composition metallurgically suitable for solder attachment.

8. The substrate according to claim 7 wherein the surface composition comprises metals including nickel, gold, palladium, or alloys thereof.

9. The substrate according to claim 1 wherein the mechanical stress includes shear stress, compressive stress, and tensile stress.

10. The substrate according to claim 1 wherein the mechanical stress includes thermo-mechanical stress.

11. The substrate according to claim 1 wherein the sheet-like base is a laminated stack of alternating insulating and conducting layers.

12. A semiconductor device comprising:
a sheet-like substrate of insulating base material, the substrate having first and second surfaces;
a plurality of conductive terminals on the first substrate surface;
at least one elastic member protruding from each terminal, the members at least partially enclosed by a reflow element attached to the respective terminal and shaped to withstand mechanical stress exerted on the element; and
a semiconductor chip assembled on the second substrate surface.

13. The semiconductor device according to claim 12 further having encapsulation material surrounding the chip.

14. An electronic system comprising:
a semiconductor device comprising:
a sheet-like substrate of insulating base material, the substrate having first and second surfaces;
a plurality of conductive terminals on the first substrate surface;
at least one elastic member protruding from each terminal, the members at least partially enclosed by a reflow element attached to the respective terminal and shaped to withstand mechanical stress exerted on the element;
a semiconductor chip assembled on the second substrate surface; and
a circuit board having a plurality of conductive terminals in locations matching the locations of the terminals on the first substrate surface; and
the reflow elements attached to the terminals on the first substrate surface also attached to the terminals of the circuit board, one by one.

15. A method for fabricating a substrate, comprising the steps of:
providing a sheet-like substrate of insulating material, the substrate having first and second surfaces;
forming a conductive terminal on the first substrate surface;
attaching at least one elastic member to the terminal so that the at least one member protrudes from the terminal, the at least one member shaped to withstand mechanical stress; and
attaching a reflow element to the terminal so that the element encloses the at least one member.

16. The method according to claim 15 wherein the step of attaching the at least one member to the terminal comprises a brazing technique.

17. The method according to claim 15 wherein the second surface of the substrate is suitable for the assembly of a semiconductor chip.

18. A method for assembling a semiconductor device comprising the steps of:
providing a sheet-like substrate of insulating material having first and second surfaces, a plurality of conductive terminals formed on the first substrate surface, and at least one elastic member attached to each terminal so that the member protrudes from the terminal, the member shaped to withstand mechanical stress;
providing a semiconductor chip;
assembling the chip on the second substrate surface; and
attaching a reflow element to each terminal so that the element encloses the at least one member.
